(19) United States
(12) Patent Application Publication
(10) Pub. No.: US 2006/0288929 A1
(43) Pub. Date: Dec. 28, 2006

(54) Polar surface preparation of nitride substrates

(75) Inventors: Glen A. Slack, Scotia, NY (US); Sandra B. Schujman, Niskayuna, NY (US); Nicholas R. Meyer, Mechanicville, NY (US); Leo J. Schowalter, Latham, NY (US)

Correspondence Address: GOODWIN PROCTER LLP;PATENT ADMINISTRATOR, EXCHANGE PLACE, BOSTON, MA, 02109-2881, US

(73) Assignee: Crystal IS, Inc., Green Island, NY (US)

(21) Appl. No.: 11/448,595

(22) Filed: Jun. 7, 2006

Related U.S. Application Data
(60) Provisional application No. 60/689,373, filed on Jun. 10, 2005.

(51) Int. Cl. C30B 23/00; C30B 25/00; C30B 28/12; C30B 28/14

(52) U.S. Cl. 117/89

(57) ABSTRACT

Fabrication of AlN substrates suitable for epitaxial deposition of high-quality nitride-based compounds thereon having at least one single-crystal and substantially planarized useful area exceeding about 1 cm² with a peak-to-valley surface topography in the useful area being less than about 50 nm is accomplished by, for example, employing an active solution that reacts non-selectively with the substrate material.

### RELATED APPLICATIONS

This application claims the benefit of and priority to U.S. Provisional Application Ser. No. 60/689,373, filed Jun. 10, 2005, the entire disclosure of which is incorporated herein by reference.

### GOVERNMENT SUPPORT

This invention was made with United States Government support under 70NANB4H3051 awarded by the National Institute of Standards and Technology (NIST). The United States Government has certain rights in the invention.

### FIELD OF THE INVENTION

The present invention relates to the preparation of semiconductor substrate surfaces, and, more specifically, to preparing Al-polarity surfaces of single-crystal AlN substrates using chemical mechanical polishing (CMP).

### BACKGROUND OF THE INVENTION

Several types of materials are routinely used to fabricate substrates for nitride-based semiconductor structures, which, in turn, can be employed as components of high-performance electronic and optoelectronic devices. For devices employing GaN or Ga₁₋ₓInₓN, the most desirable substrate would nominally be a large-area GaN single-crystal wafer. While several methods to grow GaN crystals have been proposed, none of them appears to be commercially feasible to fabricate large-area bulk crystals of GaN. Sapphire is a popular conventional substrate material, because relatively high-quality, inexpensive sapphire substrates are commercially available. However, for a number of reasons, sapphire is not particularly suited for GaN epitaxy. Single-crystal substrates of SiC present an attractive alternative to sapphire due to their close lattice match to AlN/GaN in the plane perpendicular to the c-axis (the so-called “c-plane”) and high thermal conductivity. In addition, SiC substrates can be made electrically conducting, which is attractive for some applications, including fabrication of light-emitting diodes (“LEDs”) and laser diodes (“LDs”). However, wurtzite SiC (matching the wurtzite crystal structure of GaN) is not available and the lattice mismatch along the c-axis between GaN and both 4H and 6H SiC is substantial. In addition, the chemical bonding between the Group IV elements of the SiC and the Group III or Group V elements of the nitrides is likely to create nucleation problems leading to electronic states at the interface.

It is, therefore, desirable to provide alternative substrates for commercial fabrication of nitride-based devices. Specifically, the physical and electronic properties of aluminum nitride (AlN)—its wide energy bandgap, high breakdown electric field, extremely high thermal conductivity, and low optical absorption in the visible and ultraviolet spectra—afford this material a great potential for a wide variety of semiconductor applications as a substrate material. In addition, both SiC and sapphire have a large thermal expansion mismatch with GaN between room temperature and typical temperatures used for epitaxy of the nitrides (−1100° C.), while AlN and GaN are very well matched over this same temperature range.

In addition to use as a substrate for GaN and Ga₁₋ₓInₓN, AlN is particularly well-suited as a substrate material for epitaxial growth of III-nitride-based devices for optoelectronics and RF applications where high Al content is desirable. The AlN lattice mismatch to AlₓGa₁₋ₓN alloys varies from a maximum of 2.3% difference with pure GaN, decreasing for increasing Al concentration. Low levels of dislocation densities are believed to be necessary for the fabrication of devices such as deep ultraviolet (UV,) laser diodes and high-efficiency deep-UV LEDs. Bulk AlN is highly insulating, which is very useful for high-power RF applications.

Recently, fabrication of AlN crystals having very low dislocation densities—under 10,000 cm⁻², typically, about 1,000 cm⁻² or less, and, in some regions, being substantially devoid of dislocation defects, has been demonstrated. See commonly-owned co-pending U.S. patent application Ser. No. 11/431,090 entitled “Method And Apparatus For Producing Large, Single-Crystals Of Aluminum Nitride,” incorporated herein by reference (the “'090 application”). These substrates have opened the door to the fabrication of devices such as deep-UV solid-state lasers long sought in the art but previously unavailable without high-quality native AlN substrates. Another advantage of native substrates is the availability of different orientations, such as non-polar or pre-determined, specific misorientations which are not readily obtainable by growth on foreign substrates.

Surface preparation is very important for the epitaxial growth of low dislocation density layers over semiconductor substrates. Chemical mechanical polishing (CMP) is a process that is typically used to polish surfaces of semiconductor wafers. CMP has emerged as the planarization method of choice because of its ability to planarize over longer lengths than traditional planarization techniques. In addition, it is able to remove subsurface damage, which is likely to occur with pure mechanical polishing. This subsurface damage will cause defects such as dislocations in the device layers which are grown epitaxially on the substrate surface and will degrade subsequent device performance.

CMP is a combination of a chemical reaction and mechanical action. In particular, CMP employs both physical and chemical forces to polish wafer surfaces. First, a load force is applied to the back of a wafer while it rests on a polishing pad. Both the pad and the wafer are then counter-rotated while slurry containing both abrasives and reactive chemicals is passed underneath. An active component reacts with the surface of the substrate and forms a compound that is softer than the underlying substrate material. The abrasive is selected to be harder than the newly-created compound, but softer than the substrate material, so that it polishes away the newly formed layer, while leaving the native substrate surface pristine and highly-polished. This process helps the planarization of the surface but does not introduce the undesirable subsurface damage that a purely mechanical method would cause.

It has been noted that different orientations of the crystal surface exhibit different chemical reactivity to the polishing slurries. For example, one CMP technique for polishing the AlN wafer employs a colloidal suspension of silica particles in a high-pH aqueous solution, generally obtained by dissolving potassium hydroxide and buffering it (hereafter, referred to as “hydroxide CMP”). See U.S. Pat. No. 7,037,838 incorporated herein by reference. The underlying exothermic chemical reaction is AlN_{solid}+3 H₂O_{liquid}→Al(OH)_{3 solid}+NH_{3 gas} and is carried out at room temperature. While the reactivity is relatively high for the nitrogen polarity of the c-face, it is lower for non-polar faces (m or a-faces) and decreases considerably for the aluminum polarity of the c-face. For example, high-quality non-polar surfaces and nitrogen-polarity surfaces of the AlN substrates can be readily produced with surface roughness values on the order of 3 Å for a 20 μm×20 μm area in less than a day. For a similar quality finish of the aluminum-polarity surface, however, the hydroxide CMP processing time may be on the order of several days.

In addition to the lengthy processing time, another obstacle to commercial viability of the AlN substrates for a number of device applications is the difficulty of producing smooth surfaces over a large area by CMP in the presence of any defects in the substrate. For example, since the removal rate is relatively low for a perfect, on-axis c-face with the aluminum polarity, any defects (such as dislocations, low-angle grain boundaries, and other macroscopic defects) tend to be preferentially removed, resulting in the increased surface roughness. Accordingly, conventional CMP approaches are poorly suited for preparation of the aluminum-polarity surfaces given realistic defect density levels in the aluminum nitride substrates.

The same stability of the Al-polarity surface that makes it difficult to polish also makes it the surface of choice for epitaxial growth in a variety of device applications. It is also desirable to use this surface for most HEMT designs since the piezoelectric effect and the spontaneous polarization at the AlₓGa₁₋ₓN/GaN interface are successfully used to create a high-mobility electron gas in the Al-polarity (or corresponding Ga-polarity) orientation. A successful and timely preparation of the (0001) surface of AlN into an epi-ready wafer may have broad impact on, for example, the preparation of UV laser diodes. A distinctive advantage of AlN as a substrate for laser diode fabrication is the fact that the m-face, that is the (1\overline{1}00 surface, constitutes a natural cleavage plane and is also perpendicular to the c-face. The combined advantages of a low-dislocation substrate that translates into low-dislocation epitaxial layers with a naturally forming rectangular cavity makes the availability of epi-ready AlN Al-faces greatly desirable. Another application of great interest for the aluminum-polarity substrate is for high-frequency, high-mobility RF devices, where the piezoelectric fields present in the polar orientations facilitate the formation of a two-dimensional electron gas with reduced doping.

A need therefore exists for surface-preparation techniques for polar surfaces of nitride substrates, particularly, the aluminum-polarity surface of aluminum nitride substrates, that will consistently produce a quality Al-polarity surface suitable for epitaxial growth, while considerably increasing the repeatability of the process and dramatically reducing the preparation time, thereby facilitating various commercial applications of this material.

### SUMMARY OF THE INVENTION

Generally, in one aspect, the invention features an aluminum nitride crystalline substrate suitable for epitaxial deposition of high-quality nitride-based compounds thereon with a predominantly aluminum-polarity surface. The substrate has a crystallographic orientation deviating from the (0001) crystallographic plane of aluminum nitride by less than about 10°. The surface of the substrate includes a single-crystal and substantially planarized useful area exceeding about 1 cm² with a peak-to-valley surface topography in the planarized area being less than about 50 nm.

Embodiments of this aspect of the invention include the following features. The substrate may be substantially devoid of a subsurface damage. Also, the useful area of the substrate may have a dislocation density of less than approximately 100,000 per cm²and an epitaxial layer including, or consisting essentially of, a nitride-based compound selected from the group consisting of AlN, GaN, InN and any binary or ternary combination thereof can be grown over the substrate at least on the useful area, thereby forming a laminate.

In some embodiments, the crystallographic orientation of the surface of the substrate deviates from the (0001) crystallographic plane of aluminum nitride by less than about 5°, and, in a particular embodiment, is substantially aligned with that plane. The substrate may have a diameter greater than about 25 mm and a dislocation density less than about 10,000 cm⁻².

In another aspect, the invention is directed to a method for chemical-mechanical polishing of a polar surface of a nitride-based substrate. The method includes the step of applying a slurry to the surface of the substrate. The slurry includes an active compound and a plurality of abrasive particles having a first microhardness suspended in the compound. The active compound non-selectively reacts with the surface of the substrate to form a chemically-modified surface layer having a second microhardness, the first microhardness exceeding the second microhardness. The method further includes the step of removing the chemically-modified surface layer and at least a portion of the slurry. The substrate may include, or consist essentially of, at least one nitride-based compound of one or more group III metals, wherein the surface of the substrate has a group III metal polarity. In some embodiments, the substrate comprises AlN, GaN, InN, or any binary or ternary combination thereof. The active compound may include, or consist essentially of, a fluorine-based or chlorine-based compound. In many embodiments, the active compound is water-soluble and is selected from the group consisting of: tin fluoride, antimony fluoride, and zinc chloride. In other embodiments, the active compound includes fluorinated hydrocarbon, for example, difluorohexane, or cesium fluoride.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1A-1B depict the two polar surfaces of AlN substrate, the (000\overline{1}), or nitrogen polarity, surface and the (0001), or aluminum polarity, surface, respectively.

FIG. 2 depicts a CMP apparatus suitable for polishing substrate surfaces in a CMP process according to various embodiments of the invention;

FIG. 3 is a flow chart of a process for polishing a substrate surface according to many embodiments of the invention; and

FIG. 4 depicts a more detailed process for polishing a substrate surface according to one embodiment of the invention.

### DESCRIPTION OF INVENTION

As mentioned above, single crystals of III-nitride compounds possess a number of useful properties for device applications, including improved suitability for epitaxial growth, high thermal and chemical compatibility, as well as thermal conductivity. Applications of wide-bandgap and high-temperature semiconductors include blue/UV solid-state charge injection lasers, UV optical sources and detectors, high-power microwave devices, high-power switches, and high-temperature applications.

Device fabrication typically involves the epitaxial growth of one or more device layers over a substrate. The quality of such device layer(s) depends on the quality of the underlying surface of the substrate, e.g. a III-nitride substrate. Defects of the substrate surface, such as micro-damage and surface roughness, are known to affect the quality of semiconductor devices epitaxially grown thereover. As mentioned above, conventional polishing techniques may damage the substrate surface both at a submicron scale and just under the surface in such a way that the substrate may degrade the performance of semiconductor devices fabricated thereon or even render the substrate unsuitable for epitaxial growth.

Accordingly, in its various aspects and embodiments thereof, the present invention focuses on CMP methods for surface preparation of III-nitride, particularly aluminum nitride substrates, for subsequent epitaxial growth of semiconductor devices thereon. Generally, the invention relates to a process whereby (i) the surface of the substrate is prepared for a CMP process, (ii) the CMP process is performed on the surface of the substrate, and (iii) the surface of the substrate is finished to clear the substrate surface of any active ingredients from the CMP process. The resulting substrates have flat, high-quality surfaces with negligible levels of surface roughness, defect dislocation densities and subsurface damage. Also, these polished surfaces are generally free of oxide coatings or islands.

In various aspects of the invention, the substrates are sliced from single-crystal boules, for example, by diamond annular saws or wire saws, and then the surface of each is ground and polished. The large-diameter AlN boules, for example, boules having a diameter greater than about 25 mm and a dislocation density less than about 10,000 cm⁻², can be fabricated as described in the '090 application.

As skilled artisans will readily recognize, the abrasive powder employed for mechanical grinding should have a microhardness greater than or equal to that of the crystal being ground. The objective is to remove material from the crystal surface in a short period of time and produce a smooth surface despite the possible presence of crystallographic defects. The polishing is intended to give a mirror-like finish to the surface, and leave a damage-free crystal underneath. In the polishing process, the lubricant reacts slowly with the crystal being polished. The slurry and abrasive pad are designed to continuously remove the reaction products without appreciably damaging the underlying crystal, such that the substrate is, preferably, substantially devoid of a subsurface damage.

In CMP, mechanical polishing, assisted by chemical action, removes material from high elevation features more rapidly than material at lower elevations, resulting in a surface having an improved planarity. The process is performed by mounting the wafer on a carrier. The carrier is then pressed against the rotating platen containing a polishing pad with the wafer disposed face-down against the pad. The carrier itself is also rotated. An abrasive-containing aqueous slurry is dripped onto the platen, saturating the pad. Conventionally, the slurry comprises abrasives of silica, alumina, cerium, or other nanometer-size particles suspended in an alkaline or acidic medium.

As discussed in the '838 patent, incorporated herein by reference, crystallographic orientation affects mechanical preparation of a substrate surface prior to CMP processing. For example, so-called c-face substrates are produced when the AlN crystal is sliced substantially perpendicular to the c-axis of the crystal. These c-face substrates are polar and the surfaces on the two sides of the substrate will have quite different properties. One side of the substrate is aluminum (Al) terminated (or so-called Al-polarity, c-face, or +c) and the other side is nitrogen (N) terminated (or so-called N-polarity, c-face, or −c).

When the AlN crystal is cut so that the c-axis of the crystal is contained in the plane of the substrate, a non-polar-substrate is produced wherein the two surfaces have identical behavior. Substrates that are cut at some angle away from the c-axis (other than 90°) also demonstrate some polarity effects, but these effects are not as strong as the effects of c-face substrates. C-face substrates are currently being used to produce electronic devices that take advantage of polar effects to create a high-density electron gas without any or with minimal doping. Thus, as mentioned above, in various embodiments, the invention focuses on an aluminum nitride single-crystal substrate having a predominantly aluminum-polarity surface having a crystallographic orientation substantially aligned with (0001) crystallographic plane of aluminum nitride, or only slightly deviating from it, for example by less than about 5°-10°.

As mentioned above and discussed in the '838 patent, substantial differences exist for optimal preparation of the substrates surfaces with different crystallographic orientations. The present invention contemplates surface-preparation techniques for metal-polarity surfaces of nitride-based substrates, particularly, the aluminum-polarity surface of aluminum nitride substrates, that address certain shortcomings of conventional approaches and consistently produce a high-quality surface suitable for epitaxial growth.

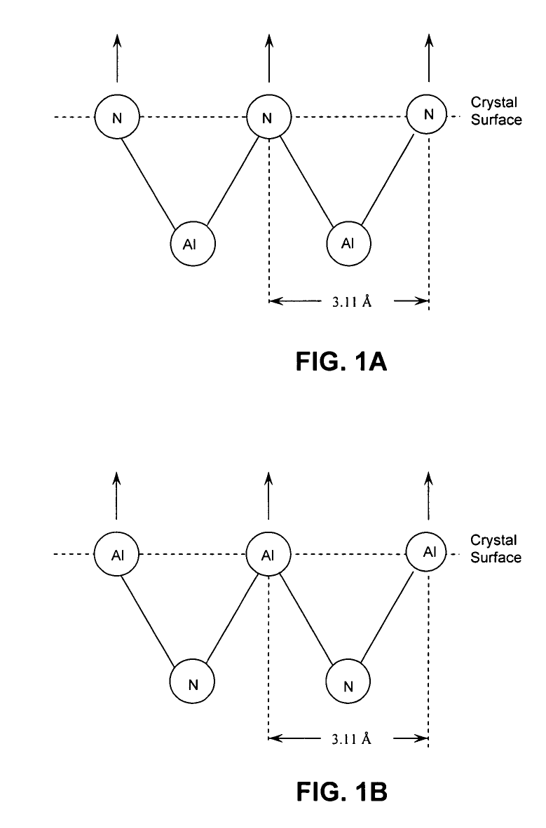

In general, the above differences can be understood from the stereochemistry of AlN with reference to FIGS. 1A-1B. As skilled artisans will readily understand, for an ideal bulk crystal terminated on the nitrogen polarity (before any surface reconstruction or contamination can occur), single nitrogen bonds perpendicular to the crystal surface will project out into space while a surface terminated on the aluminum polarity will have single aluminum bonds projecting out into space perpendicular to the crystal surface. It has been observed that the (000\overline{1}) surface, i.e. the aluminum-polarity side of the substrate is very stable against etching in a solution containing hydroxide ions, unlike the (0001) surface having the nitrogen polarity, which relatively easy to etch. Similar results have been observed for crystals of other nitrides where the c-face with the metal polarity is much more stable than the surface with the nitrogen polarity. While not being bound by a particular theory, it is believed that this is consistent with the observation that H⁺ ions will tend to attach to the nitrogen dangling bonds on the nitrogen-polarity surface while OH⁻ ions will tend to attach to the aluminum dangling bonds on the aluminum-polarity surface. Since the hydrogen ions are very small, the underlying N—Al bonds on the nitrogen-polarity surface remain open to interaction with other ions in the solution. This makes it easy to remove the nitrogen atom through the formation of ammonia while allowing the underlying Al form a hydroxide layer. However, the aluminum-polarity surface behaves differently. The relatively large size of the hydroxide ions makes further interactions with the underlying Al—N bonds on the aluminum-polarity surface much more difficult. In addition, the hydroxide layer on the aluminum polarity surface may be converted into an aluminum oxide layer during the hydroxide CMP process further protecting the surface because of the relative hardness of Al₂O₃.

In Table 1, the relative micro-hardness of different materials are shown. During the CMP process, it is desirable to form a surface layer that is softer than the underlying crystal substrate through chemical reaction with the active agent in the slurry. The slurry should then also include an abrasive with a micro-hardness that is greater than the surface layer that is formed. Thus, silica is effective is removing hydroxides and fluorides of Al but can not be expected to be effective in removing an aluminum oxide layer.

| Material | Micro-hardness (kg/mm²) |
|---|---|
| α-SiO₂ | 725 |
| AlF₃ | <550 |
| AlN | 1225 |
| α-Al₂O₃ | 2450 |
| β-Si₃N₄ | ˜2700 |
| Al(OH)₃ | ˜86 |
| γ-AlO(OH) | ˜145 |

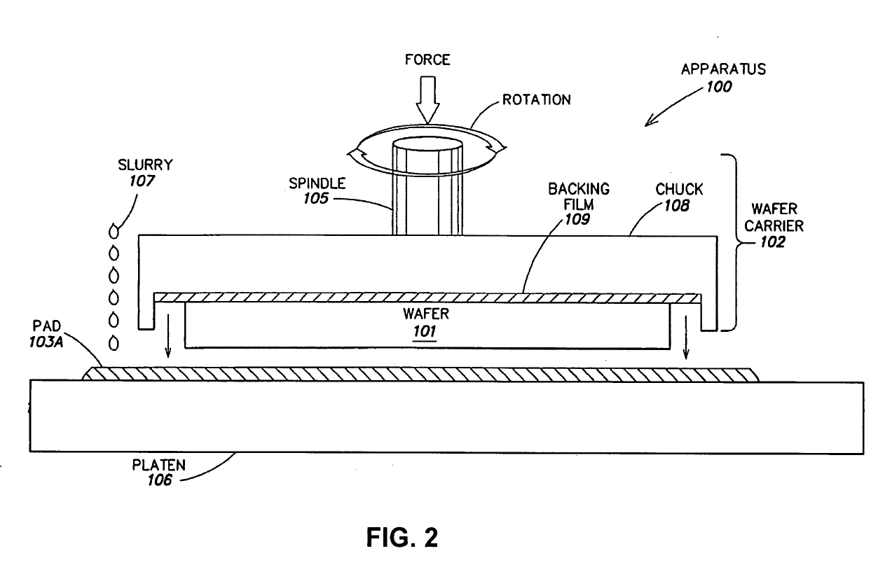

Referring to FIG. 2, in various embodiments, an apparatus suitable for polishing substrate surfaces in a CMP process includes a wafer carrier 102 having a wafer 101 to be polished mounted thereon. In some embodiments, the wafer includes at least one nitride-based compound of one or more group III metals and the surface of the substrate has a group III metal polarity. For example, in some versions of these embodiments, the substrate includes AlN, GaN, InN, or any binary or ternary combination thereof.

The carrier 102 generally includes a backing film 109 positioned between wafer 101 and a chuck 108 which holds the wafer and the wafer carrier 102. Wafer carrier 102 is rotated by a spindle 105. A force is applied to the wafer carrier 102 to contact the wafer 101 with a polishing pad 103. The pad 103 is adhered to a rotatable platen 106. Further, a slurry 107 is applied to the pad 103 and the drip rate is controlled, for example, by a flow-control dispenser (not shown). In some embodiments of the invention, a combination of slurry components with different dripping rates is employed. It should be appreciated, however, that other CMP tools and/or polishing apparatus may be used and the invention is not limited to any particular CMP tools or polishing configurations.

According to one aspect of the invention, the CMP process may involve polishing the substrate using a slurry including an abrasive suspension in a solution capable of modifying the surface material of the substrate and creating a finished surface suitable for epitaxial growth. As mentioned above, the active solution chemically modifies the surface of the substrate, forming a compound that is softer than the underlying substrate material. The abrasive is selected to be harder than the newly-created compound, but softer than the substrate material, so that it polishes away the newly formed layer, while leaving the native substrate surface pristine and highly-polished. In many embodiments, the slurry includes abrasive materials having microhardness values between 800 and 1400 kg/mm².

As mentioned above, conventional polishing techniques are poorly suited for producing smooth surfaces over large areas in the presence of any defects in the substrate, because these defective regions, such as dislocations, low angle grain boundaries, and other macroscopic defects tend to be preferentially etched. Many device applications require very low peak-to-valley values of the surface topography of the useable area. Given typical defect densities even in the high-quality AlN crystals, e.g. exceeding 100-500 per cm², such levels of surface roughness are very difficult to achieve for an on-axis c-face substrates with the aluminum polarity. The CMP approach employed in various embodiments of the present invention, however, contemplates fabrication of AlN substrates having at least one single-crystal and substantially planarized area of the aluminum-polarity surface for epitaxial deposition of high-quality nitride-based compounds thereon (referred to as a “useful area”) by employing the active solution that reacts non-selectively with the substrate material, i.e. etches various areas of the substrate material at substantially similar removal rates without regard for any crystallographic defects in the substrate.

In some embodiments of the invention, the useful area exceeds about 1 cm² with a peak-to-valley surface topography therein being less than about 50 nm, and, in some version of these embodiments, less than about 20-30 nm. Preferably, a dislocation density in the useful area is less than approximately 100,000 per cm². One or more epitaxial layers including, or consisting essentially of, a nitride-based material selected from the group consisting of AlN, GaN, InN and any binary or ternary combination thereof can be grown over the substrate at least on the useful area, thereby forming a laminate, for example, as described in the '090 application.

In various embodiments, the active solution non-selectively reacing with the substrate material includes a fluorine-based or chlorine-based active compound, forming, in case of the AlN substrates, AlF₃ or AlCl₃ salts that are softer than both AlN and alumina. For example, in some embodiments, the slurry includes alumina, cerium aluminate, or lanthanum aluminate particles suspended in a solution of a water-soluble active compound, for example, an acid fluorine aqueous solution having a pH between 0 and 4. In many embodiments, the active compound includes, or consists essentially of, tin fluorides (SnF₂ or SnF₄), antimony fluorides (SbF₃ or SbF₅), or zinc chloride (ZnCl₂) and is prepared by dissolving these salts in water. In other embodiments, the slurry is designed to exclude hydroxide ions and, in some versions, is composed by suspending the above abrasives in an aliphatic fluorinated hydrocarbon, such as difluorohexadecane. In other versions of these embodiments, the slurry includes the above abrasives or, for example, calcium fluoride, magnesium fluoride, titanium oxide, or cerium oxide, suspended in cesium fluoride dissolved in anhydrous hydrofluoric acid.

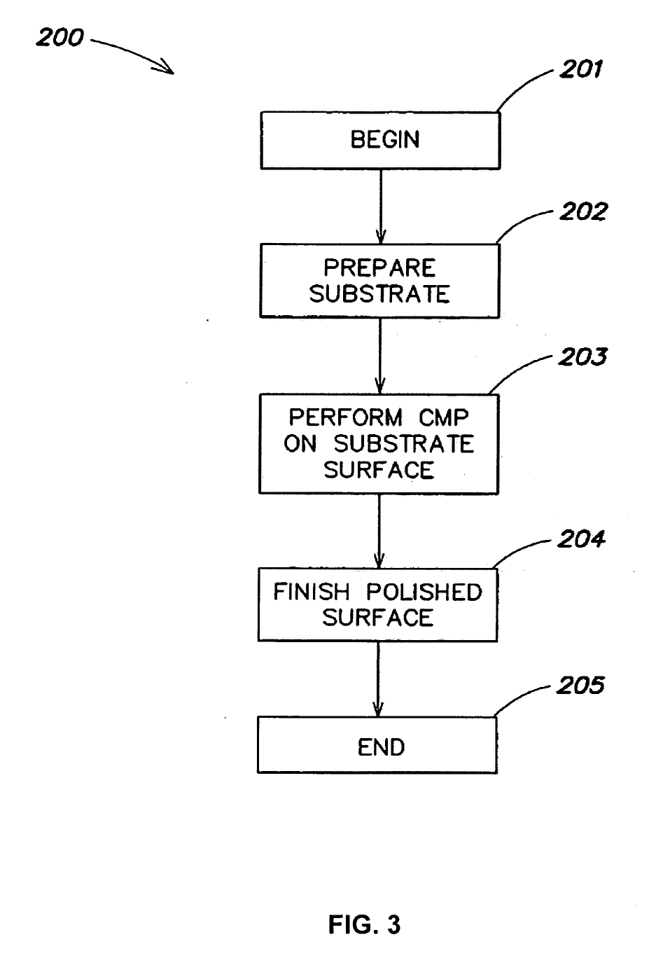

Referring to FIG. 3, a process 200 for polishing a substrate according to various embodiments of the invention begins at block 201. At block 202, the substrate is prepared for polishing. This may include removal of contamination from the surface of the substrate, the polishing apparatus and environment. Such contamination is generally responsible for the introduction of surface defects during the polishing process. At block 203, a CMP process is performed on the substrate surface. In the case of the Al-polarity c-face of AlN, the CMP process may include polishing the surface using a slurry having a fluorine-based solution discussed above in connection with FIG. 1. At block 204, the polished wafer is finished. This may involve, for example, removal of the wafer from the polishing apparatus and carefully cleaning the wafer to remove any reactive agents introduced by the polishing process. At block 205, process 200 ends.

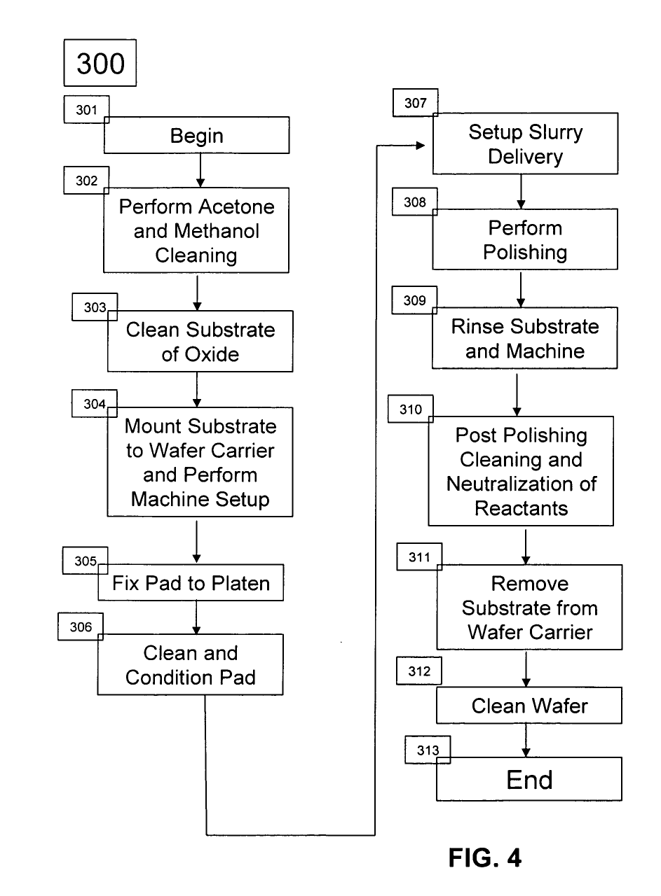

FIG. 4 shows a process 300 for polishing a substrate according to various embodiments of the invention in more detail. At block 301, process 300 begins by preparing the substrate for the CMP. More particularly, the environment and wafer are cleaned of possible contaminants, and the polishing apparatus is adjusted to apply the correct polishing force to the wafer. The following example is a procedure for preparing the substrate according to one embodiment of the invention:

I. Preparation of Substrate and Apparatus for CMP Process

The wafer surface and mounting block should be cleaned of substantially all possible contamination particles (e.g., wax, dirt, and larger mechanical grit particles). This is typically done with, for example, organic solvent (e.g., by acetone and/or methanol) cleaning performed at block 302. Also, any remaining particles from previous processes (e.g., CMP fluid residue) should be cleaned from all surfaces that contact the polishing area so as to reduce the likelihood of contaminating the polishing surface and potentially damaging the substrate surface.

The substrate surface should be cleaned of oxides prior to the CMP process. For this a bath of ammonium acid fluoride at a temperature between 120° C. and 130° C., phosphoric acid at 70° C., or liquid lithium bath at a temperature ranging from 185° C. and 195° C. can be employed. Any of these cleaning processes should be performed in an inert atmosphere. For the ammonium acid fluoride and phosphoric acid it is possible to use Teflon covered beakers and tweezers, in either nitrogen or argon atmosphere. In the case of a liquid lithium bath, it is possible to use stainless steel and the use of an Ar atmosphere is desirable to avoid the formation of lithium nitride that can contaminate the wafer surface (Block 303).

The mounting block is then prepared to hold the substrate at block 304. For example, the wafer may be adhered to a surface of the mounting block. This mounting block has a weight that applies a downward pressure on the substrate. This should be considered if applying extra pressure on the substrate for the CMP process. In one embodiment, an Engis machine model AM15 with pneumatic assisted pressure spindle is employed, and the equipment parameters are (i) the lap pressure (between 10 and 15 psi), the platen rotation speed (between 90 and 120 rpm) and the matching spindle rotation (between 90 and 120 rpm). For those skilled in the art, however, using a different machine with the following parameters should lead to equivalent results: a pressure applied to the substrates ranging from 1×10⁴ N/m² and 5×10⁵ N/m², and a polishing speed of the substrate in the range between 0.5 m/s and 5 m/s. A CMP process may be then performed on the prepared substrate surface as described below.

II. CMP Process

The following is a detailed sequence of steps, to prepare an AlN substrate surface and the drip rates for a CMP process according to various embodiments of the invention.

A new “Chemic Cloth” or “Plano Cloth” fine polishing pad or any other suitable synthetic fine polishing pad should be adhered to the polishing table (platen). Generally, such a polishing pad has a self-adhesive backing to adhere it to the platen surface. At block 305, the polishing pad is adhered to the platen surface. For best results, the polishing pad should be applied to the polishing platen so as to avoid any space underneath the pad causing it to be uneven.

At block 306, the pad surface may be cleaned and conditioned. During this time, the surface of the pad should be thoroughly rinsed with filtered de-ionized water. This is performed to ensure that both the pad and the fixture have been completely cleaned of all dust and cross-contaminating particles. Conditioning the pad may involve, for example, rotating the platen while applying pressure with a conditioning ring and spraying de-ionized water.

At block 307, the slurry (or slurry components) drip rates and rotation of the fixture should be set for polishing. During this rotation cleaning of the surface, the drip/s rate/s should be set using an appropriate flow-control dispenser, for example, a peristaltic pump.

Following the confirmation of the proper rate and with the observation of proper rotation of the fixture, the wafer may be placed on the pad surface and pressure may be applied to begin the CMP process. At block 308, the wafer is polished employing the slurry described above.

III. Finishing

According to one embodiment of the invention, the wafer is cleaned to remove any contamination from the CMP process, and to remove traces of reacting chemicals from the substrate surface to stop any residual reactions with the substrate.

At block 309, the wafer is rinsed. At the end of the CMP process, the wafer should be lifted from the polishing surface and immediately rinsed, for example, with distilled water. This ensures that the reaction between the AlN and any of the active ingredients in the slurry is stopped, and removes abrasives that may dry to the prepared surface. A solution of sodium bicarbonate can be used to neutralize any acid remnants on the machine.

Following this rinsing, the wafer is carefully cleaned at block 310 with suitable organic solvents to remove the agent bonding the substrate to the substrate holder. Mounting wax is soluble in these solvents and common wafer holding techniques may be used to hold the substrates, as well as other adhesive film and vacuum chucking techniques. At block 311, substrate debonding procedures are performed.

Following the CMP processing, the wafer surface should be cleaned very well at block 312. For example, the sample surface may be cleaned prior to removal of the substrate from the mounting block, and then the entire substrate may be cleaned when removed. At block 313, process 300 ends.

The modifications to the various aspects of the present invention described hereinabove are merely exemplary. It is understood that other modifications to the illustrative embodiments will readily occur to persons with ordinary skill in the art. All such modifications and variations are deemed to be within the scope and spirit of the present invention as defined by the accompanying claims. All of the patents, patent applications, journal articles, and other references mentioned above are incorporated herein by reference.

What is claimed is:

1. An aluminum nitride crystalline substrate suitable for epitaxial deposition of high-quality nitride-based compounds thereon, the substrate having a predominantly aluminum-polarity surface comprising a single-crystal and substantially planarized useful area exceeding about 1 cm², a peak-to-valley surface topography in the useful area being less than about 50 nm, the surface having a crystallographic orientation deviating from the (0001) crystallographic plane of aluminum nitride by less than about 10°.

2. The crystalline substrate of claim 1 substantially devoid of a subsurface damage.

3. A laminate comprising (i) the crystalline substrate of claim 1 having a dislocation density in the useful area of less than approximately 100,000 per cm² and (ii) an epitaxial layer grown thereon and comprising a nitride-based compound selected from the group consisting of AlN, GaN, InN and any binary or ternary combination thereof.

4. The substrate of claim 1 wherein the crystallographic orientation deviates from the (0001) crystallographic plane of aluminum nitride by less than about 5°

5. The substrate of claim 1 wherein the surface is substantially aligned with the (0001) crystallographic plane of aluminum nitride.

6. The substrate of claim 1 having a diameter greater than about 25 mm and a dislocation density less than about 10,000 cm⁻².

7. A method for chemical-mechanical polishing of a polar surface of a nitride-based substrate, the method comprising the steps of:
(a) applying a slurry to the surface of the substrate, the slurry comprising an active compound and a plurality of abrasive particles having a first microhardness suspended therein, the active compound non-selectively reacting with the surface of the substrate to form a chemically-modified surface layer having a second microhardness, the first microhardness exceeding the second microhardness; and
(b) removing the chemically-modified surface layer and at least a portion of the slurry.

8. The method of claim 7 wherein the substrate comprises at least one nitride-based compound of one or more group III metals, the surface of the substrate having a group III metal polarity.

9. The method of claim 7 wherein the substrate comprises AlN, GaN, InN, or any binary or ternary combination thereof.

10. The method of claim 7 wherein the active compound comprises a fluorine-based or chlorine-based compound.

11. The method of claim 10 wherein the active compound is water-soluble.

12. The method of claim 11 wherein the water-soluble active compound is selected from the group consisting of: tin fluoride, antimony fluoride, and zinc chloride.

13. The method of claim 7 wherein the active compound comprises fluorinated hydrocarbon or cesium fluoride.

14. The method of claim 13 wherein the active compound comprises difluorohexane.

15. An aluminum nitride crystalline substrate suitable for epitaxial deposition of high-quality nitride-based compounds thereon fabricated by the method of claim 7.
